(19) United States
(12) Patent Application Publication
(10) Pub. No.: US 2010/0019829 A1
(43) Pub. Date: Jan. 28, 2010

(54) TURN ON-OFF POWER CIRCUIT FOR DIGITAL SYSTEMS

(76) Inventors: ERIK J. CEGNAR, MOSCOW, ID (US); FRED JESSUP, MOSCOW, ID (US); DAVID G. ALEXANDER, MOSCOW, ID (US); MICHAEL MAUGHAN, MOSCOW, ID (US)

Correspondence Address: DYKAS, SHAVER & NIPPER, LLP, P.O. BOX 877, BOISE, ID, 83701-0877, US

(21) Appl. No.: 12/510,841

(22) Filed: Jul. 28, 2009

Related U.S. Application Data
(60) Provisional application No. 61/084,029, filed on Jul. 28, 2008.

(51) Int. Cl. H03K 17/687

(52) U.S. Cl. 327/434

(57) ABSTRACT

A turn-on circuit that is used to provide power to a system or other circuit when activated. The circuit is activated through depression of a momentary button or other similar device. The circuit is deactivated by a separate digital signal from said system or said other circuit and when deactivated no longer provides power to the system.

### PRIORITY/CROSS-REFERENCE TO RELATED APPLICATIONS

This application claims the priority date of the provisional application entitled TURN ON-OFF POWER CIRCUIT FOR DIGITAL SYSTEMS filed by Erik J. Cegnar, Fred Jessup, Michael Maughan and David G. Alexander on Jul. 28, 2008 with application Ser. No. 61/084029, the disclosure of which is incorporated by reference.

### FIELD OF THE INVENTION

The field of the invention relates to an electrical circuit that, from two separate signals, controls power to a system or circuit.

### BACKGROUND OF THE INVENTION

The use of digital systems in consumer products is wide and growing. Systems are often turned on and off by means of a toggle switch where the system receives power when the switch is on and does not receive power when the switch is off. Systems may also employ a conventional flip-flop type circuit. A conventional flip-flop circuit is limited in the input voltage range and always consumes power, which is not desirable for battery-powered systems.

These two means for turning on or off systems is limiting. Digital systems often need to perform processes after the user turns the system off. The toggle switch does not provide for an interim state before the power is turned off. Therefore, post processes cannot take place once the toggle switch is turned off. Also, it is beneficial that a system is able to use the power button as an input button with the initial button function being to turn the system on. The button can then be used as an input button to perform many functions including indicating to the system to turn itself off. Neither the toggle nor the flip-flop circuit can be used as an additional input button.

### SUMMARY OF THE DISCLOSURE

Disclosed is a turn-on circuit that is used to provide power to a system or other circuit when activated. The circuit is activated through depression of a momentary button or other similar device. The circuit is deactivated by a separate digital signal from said system or said other circuit and when deactivated no longer provides power to the system. During momentary button (100) depression, said turn-on circuit outputs a signal to a digital system indicating a button depression. The said turn-on circuit consumes no power until the button is pressed. The said turn-on circuit operates over a wide range or input voltages.

The said turn-on circuit provides two distinct advantages. One, it provides a method by which a system can turn itself of, and two, it allows a system's power button to be used as an input button as well. The ability of a system to turn itself off is advantageous because a system may receive an input to turn off but may first need to perform a process before it powers down. Because said turn-on circuit can be used as a power turn-on button and a user input button, said turn-on circuit can be used to develop systems with advanced button in put schemes and functionality.

An example of this functionality is a system operating one program that is only on when the button is depressed and turns off when it is no longer depressed. That same system, operating a different program, may stay on after one click and enter a different functional mode temporarily if the button is depressed and held. The system would also then be capable of incrementing modes of operation for each button depression and then turn off after all modes have been cycled through. The system would also be one that would be able to discern and perform functions based on multiple clicks, for example single, double, etc.

### BRIEF DESCRIPTION OF THE DRAWING

FIG. 1 is a schematic view of one embodiment of the present invention.

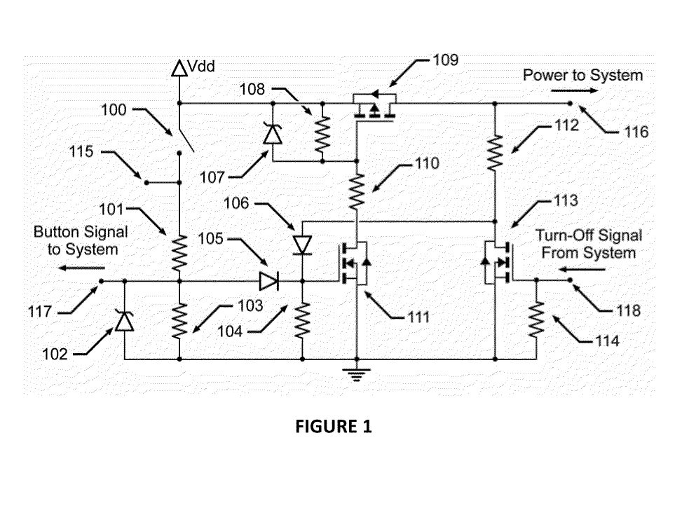

### DESCRIPTION OF THE PREFERRED EMBODIMENTS

While the invention is susceptible of various modifications and alternative constructions, certain illustrated embodiments thereof have been shown in the drawings and will be described below in detail. It should be understood, however, that there is no intention to limit the invention to the specific form disclosed, but, on the contrary, the invention is to cover all modifications, alternative constructions, and equivalents falling within the spirit and scope of the invention as defined in the claims.

In the following description and in the FIGURE, like elements are identified with like reference numerals. The use of “e.g.,” “etc,” and “or” indicates non-exclusive alternatives without limitation unless otherwise noted. The use of “including” means “including, but not limited to,” unless otherwise noted.

The circuit is activated by the depression of a momentary switch (100) or the application of a voltage to node 115. Resistors 101 and 103 form a voltage divider, which acts to reduce the voltage over resistor 103. When the button is depressed or a voltage is applied to node 115, a current flows through resistor 101, diode 105, and resistor 104. A voltage is generated at the gate of mosfet 111. The gate voltage causes the mosfet to conduct and current flows through resistor 108, resistor 110, and the mosfet 111. Because resistor 108 is significantly larger than resistor 110, the majority of the voltage drop is over resistor 108. This voltage causes the voltage Vsg of mosfet 109 to be greater than its threshold voltage. The mosfet 109 then conducts and provides power to a system at node 116.

When on, the mosfet 109 provides a voltage to the gate of mosfet 111, through resistor 112 and diode 106. This positive feedback system causes the circuit to latch and continue to be active after the momentary switch 100 is no longer depressed, or the voltage at node 115 is removed.

While the momentary switch 100 is depressed or a voltage is applied to node 115, there is an output voltage at node 117. This voltage indicates that the button is depressed or a voltage is being applied to node 117. Zener diode 102 ensures that the voltage at node 115 does not exceed a systems maximum input voltage specification. The diode 105 ensures that an output voltage at node 117 is not present once the momentary switch (100) is not depressed or once a voltage is not being provided to node 115.

When a voltage is applied to node 118, this causes mosfet 113 to conduct. This causes the voltage Vsg at the gate of mosfet 111 to drop below its threshold voltage. The mosfet (111) then turns off and stops conducting current. Once the mosfet stops conducting, the current through resistors 108 and 110 goes to 0, and the Vsg of mosfet 109 is then 0 volts. This causes the mosfet to turn off and therefore power is no longer provided to the system. After the circuit is deactivated the voltage at node 118 may return to 0 volts and the circuit will only be reactivated by depressing momentary switch 100 or applying a voltage to node 115.

In the event that at turn off signal is applied to node 118 while the button is depressed or a voltage is applied to node 115, the circuit will remain active and supplying power to the system. In this scenario, the diode 106 prevents the mosfet 113 from pulling the gate of mosfet 111 down. Therefore, mosfet 111 remains on. If the turn-off signal is present at node 118 and the button discontinues being depressed or voltage at node 115 is removed, the circuit will immediately become deactivated and stop supplying power to the system at node 116.

Zener diode 107 and resistor 110, prevent the voltage Vsg of mosfet 109 from going beyond its maximum rated source-to-gate voltage. A zener diode is sometimes integrated into mosfets to protect the gate.

Resistors 104, 108, and 114 ensure that mosfets 111, 109, and 113 respectively remain off when a voltage is not applied from gate to source.

While there is shown and described the present preferred embodiment of the invention, it is to be distinctly understood that this invention is not limited thereto but may be variously embodied to practice within the scope of the following claims. From the foregoing description, it will be apparent that various changes may be made without departing from the spirit and scope of the invention as defined by the following claims.

The purpose of the Abstract is to enable the public, and especially the scientists, engineers, and practitioners in the art who are not familiar with patent or legal terms or phraseology, to determine quickly from a cursory inspection, the nature and essence of the technical disclosure of the application. The Abstract is neither intended to define the invention of the application, which is measured by the claims, nor is it intended to be limiting as to the scope of the invention in any way.

Still other features and advantages of the claimed invention will become readily apparent to those skilled in this art from the following detailed description describing preferred embodiments of the invention, simply by way of illustration of the best mode contemplated by carrying out my invention. As will be realized, the invention is capable of modification in various obvious respects all without departing from the invention. Accordingly, the drawings and description of the preferred embodiments are to be regarded as illustrative in nature, and not as restrictive in nature.

What is claimed is:

1. An on-off switch circuit for use with an off signal, said on-off switch circuit comprising:
a switch, said switch having two positions, a first open position and a second position and a second closed position, said switch configured to turn a control MOSFET on for turning an on-off switch circuit on;
an off signal, said off signal having two modes, a low mode and a high mode, wherein in said low mode said off signal is zero volts, wherein in said high mode said off signal is greater than zero volts, said off signal configured for turning off said on-off switch circuit when said off signal is in said high mode and said switch is in said first open position; and
a control MOSFET configured to be ON when said switch is in said second closed position, when said switch is in said second closed position and said switch is returned to said first open position said control MOSFET is configured to remain in said ON state until a turn off MOSFET is in said ON state;
a switching MOSFET configured to control power to an electronic system, said switching MOSFET configured to be in said ON state when said control MOSFET is in said ON state, said switching MOSFET configured to be in said OFF state when said control MOSFET is in said OFF state; and
said turn off MOSFET configured to be ON when said off signal is in said high mode, said turn off MOSFET configured to be OFF when said off signal is in said low mode, said turn off MOSFET configured to turn control MOSFET OFF when said turn off MOSFET is ON and said switch is in its first open position;
wherein each of said MOSFET devices having two states, ON and OFF, wherein when said MOSFET devices are ON said MOSFET devices are configured to conduct electric current, wherein when said MOSFET devices are OFF said MOSFET are configured to prevent electric current flow.

2. The circuit of claim 1, wherein said switch is a momentary switch.

3. The circuit of claim 1, wherein said switch is activated by a voltage applied to a node.
